(19) United States
(12) Patent Application Publication
(10) Pub. No.: US 2002/0025608 A1
(43) Pub. Date: Feb. 28, 2002

(54) Memory module, method of manufacturing the memory module, and test connector using the memory module

(75) Inventors: Naoyuki Shinonaga, Nagano (JP); Hideyuki Akagi, Nagano (JP); Syuuichi Osaka, Nagano (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 09/798,943

(22) Filed: Mar. 6, 2001

(30) Foreign Application Priority Data
Aug. 29, 2000 (JP) 2000-259661

(51) Int. Cl. H01L 21/66; G01R 31/26; H01L 21/44; H01L 21/48; H01L 21/50; H01L 23/02; H01L 23/28

(52) U.S. Cl. 438/127; 438/15; 438/17; 257/678; 257/685; 257/787

(57) ABSTRACT

Testing of memory chips is facilitated. Further, memory chips which have failed a test can be readily replaced with new non-defective memory chips. Efforts and costs required for replacing defective memory chips with non-defective memory chips can be reduced. A memory module has a circuit board having mounted thereon a plurality of bonding pad groups, a plurality of contact pad groups, a plurality of jumper pad groups, and a plurality of through hole groups, which are assigned to respective chip mount areas. According to a method of manufacturing a memory chip, memory chips are tested through use of the contact pad groups before being encapsulated with molding resin, and there is used a test connector having POGO pins which are brought into contact with corresponding contact pad groups.

### BACKGROUND OF THE INVENTION

1. Field of the Invention

The present invention relates to a memory module using semiconductor memory, and more particularly, to a memory module which is manufactured by means of placing a plurality of semiconductor memory chips on a multilayer circuit board, connecting the memory chips to the circuit board through bonding, and sealing with molding resin the circuit board having the memory modules bonded thereon; to a method of manufacturing the memory module; and to a test connector using the memory module.

2. Background Art

Japanese Patent Application Laid-Open No. 256474/1998 describes a memory module which is manufactured by means of placing a plurality of semiconductor chips (bare chips) on a circuit board, connecting the chips to the circuit board through bonding, and sealing with molding resin the circuit board having the chips mounted thereon. As compared with a memory module manufactured by means of mounting plastic-packaged semiconductor memory chips on a circuit board, the memory module of the foregoing type enables a reduction in mounting areas and has the advantage of increasing the usable volume and the degree of integration of a memory module.

However, there has not been proposed a memory module of this type that has a construction which takes into consideration testing of a semiconductor memory chip. In the event that a faulty semiconductor memory chip is found by means of testing a semiconductor memory chip which has been sealed with molding resin, the memory chip must be replaced with another memory chip by removal of molding resin, thus involving financial loss and consumption of effort. Particularly, in the case of a memory module using a multilayer circuit board, a memory chip must be replaced so as to protect other circuit elements on the multilayer circuit board from damage, thus involving substantial financial loss and consumption of much effort. In order to avoid occurrence of financial loss or consumption of unnecessary effort, before being mounted a semiconductor memory chip must be tested under the assumption that the semiconductor memory chip has been mounted. To this end, a special test socket must be prepared, which in turn adds to cost.

### SUMMARY OF THE INVENTION

The present invention proposes an improved memory module which enables efficient testing of semiconductor memory chips before being sealed with molding resin and while all the chips are mounted on a multilayer circuit board.

The present invention also proposes an improved memory module which enables efficient testing of semiconductor memory chips before being sealed with molding resin and while all the chips are mounted on a multilayer circuit board, and which is compatible with semiconductor memory chips of different sizes.

The present invention also proposes an improved memory module which enables efficient testing of semiconductor memory chips before being sealed with molding resin and while all the chips are mounted on a multilayer circuit board and which, if some semiconductor memory chips are determined to be defective by the test, enables replacement of the defective chips with new chips in a simplified manner.

The present invention also proposes an improved method of manufacturing a memory module which enables efficient testing of semiconductor memory chips before being sealed with molding resin and while all the chips are mounted on a multilayer circuit board and which, if some semiconductor memory chips are determined to be defective by the test, replaces the defective chips with new chips and seals all the semiconductor memory chips after having inspected the new chips until the new chips pass the test.

The present invention also proposes an improved method of manufacturing a memory module which enables efficient testing of semiconductor memory chips before being sealed with molding resin and while all the chips are mounted on a multilayer circuit board of multi-row construction and which, if some semiconductor memory chips are determined to be defective by the test, replaces the defective chips with new chips and seals all the semiconductor memory chips after having inspected the new chips until the new chips pass the test.

The present invention also proposes a test connector for use in efficiently testing all semiconductor memory chips before the chips are sealed with molding resin and while the semiconductor memory chips are mounted on a multilayer circuit board.

According to one aspect of the present invention, a memory module comprises a multilayer circuit board having a plurality of chip mount areas on which a plurality of semiconductor memory chips are to be mounted; a plurality of bonding pad groups which are formed on the multilayer circuit board so as to correspond to the respective chip mount areas and are respectively connected to electrode pads of the corresponding semiconductor memory chips; a plurality of contact pad groups which are formed on the multilayer circuit board so as to correspond to the respective bonding pad groups and are respectively connected to corresponding bonding pad groups; a plurality of jumper pad groups which are formed on the multilayer circuit board so as to correspond to the respective contact pad groups and are respectively connected to other connective portions or other circuit elements provided on the multilayer circuit board; a plurality of jumper wires for interconnecting the jumper pad groups and corresponding contact pad groups respectively; and molding resin for encapsulating the memory chips, the bonding pad groups, the contact pad groups, the jumper pad groups, and the jumper wires.

The memory module according to the present invention has a set of contact pad groups connected to respective memory chips and a set of jumper pad groups connected to other connection portions or circuit elements of a multilayer circuit board. The memory chips can be tested by means of utilization of the group of contact pads before the memory module is encapsulated with molding resin. As compared with a case where memory chips are tested after having been encapsulated with resin, the present invention can reduce the efforts and costs required for replacing defective memory chips with new, non-defective memory chips. Since memory chips can be tested while mounted on a multilayer circuit board on which the chips are to be mounted, use of special test sockets is obviated.

According to another aspect of the present invention, in a method of manufacturing a memory module, in a preparation step a multilayer circuit board having a plurality of chip mount areas for use in mounting a plurality of semiconductor memory chips, a plurality of bonding pad groups assigned to the respective chip mount areas, a plurality of contact pad groups respectively connected to the corresponding bonding pad groups, and a plurality of jumper pad groups which are respectively arranged so as to correspond to the respective contact pad groups and are respectively connected to other circuit portions or circuit elements is prepared. Next, in a first connection step semiconductor memory chips are mounted in the respective chip mount areas after the preparation step and electrode pads of the respective semiconductor memory chips are connected to the respective bonding pad groups assigned to the respective chip mount area. Next, in a test step the respective semiconductor memory chips are tested by way of the respective contact pad groups after the first connection step, the semiconductor memory chips which are determined to have failed the test are taken measures, and the semiconductor memory chips are tested again until the semiconductor memory chips are determined to have passed the test. Next, in a second connection step the respective contact pad groups are connected to corresponding jumper pad groups after the test step. Next in a molding step the semiconductor memory chips, the bonding pad groups, the contact pad groups, and the jumper pad groups are encapsulated with molding resin after the second connection step.

Under the method of manufacturing a memory module according to the present invention, memory chips are tested before being encapsulated with molding resin, by means of utilization of a group of contact pads. As compared with a memory module which is subjected to a chip test after having been encapsulated with resin, a memory module according to the present invention can reduce efforts and costs required for replacing defective memory chips with non-defective memory chips. Further, memory chips can be tested while mounted on a multilayer circuit board on which the memory chips are to be mounted, and hence use of a special test socket is obviated. Further, memory chips are tested while separated from a module circuit including a set of jumper pad groups, and hence memory chips can be tested efficiently and accurately.

According to another aspect of the present invention, a test connector for use in testing semiconductor memory chips in combination with a multilayer circuit board, the circuit board including a plurality of chip mount areas in which a plurality of semiconductor memory chips are to be mounted, a plurality of bonding pad groups assigned to the respective chip mount areas and respectively connected to electrode pads of the corresponding semiconductor memory chip, a plurality of contact pad groups respectively connected to the corresponding bonding pad groups, and a plurality of jumper pad groups which are arranged so as to correspond to the respective contact pad groups and are respectively connected to other circuit pads or circuit elements. The test connector comprises a plurality of POGO pin groups provided on the circuit board so as to correspond to the respective contact pad groups; and a plurality of connector terminals provided on the circuit board and connected to the respective POGO pin groups.

The test connector for use with a memory module according to the present invention is provided with a group of POGO pins which are brought into contact with all contact pads of all contact pad groups. Hence, testing of memory chips can be implemented in a shorter period of time.

### BRIEF DESCRIPTION OF THE DRAWINGS

FIG. 1 is a perspective view of a memory module according to a first embodiment, showing the memory module while molding resin applied over the module is removed.

FIG. 2 is a top view showing the layout of the upper surface of the memory module shown in FIG. 1.

FIG. 3 is an enlarged top view showing a portion of the memory module shown in FIG. 2.

FIG. 4 is a top view showing the memory module shown in FIG. 3 before the chips are wire-bonded.

FIG. 5 is an enlarged top view showing a portion of a memory module according to a second embodiment of the present invention.

FIG. 6 is a flowchart of a manufacturing method according to a third embodiment.

FIG. 7 is a top view of a memory module according to the fourth embodiment.

FIG. 8 is a flowchart of a manufacturing method according to the fifth embodiment.

FIG. 9A to 9C are enlarged views showing circuit patterns according to the sixth embodiment.

FIG. 10 is a flowchart of a manufacturing method according to the seventh embodiment.

FIG. 11 is a perspective view showing a multilayer circuit board according to the eighth embodiment.

FIG. 12A to 12C are a top view, a right side elevation view and a side view showing a test connector for use with the memory module according to the ninth embodiment.

FIG. 13 is a schematic cross-sectional view showing the construction of a single POGO pin according to the ninth embodiment.

FIG. 14 is a perspective view showing a test connector and a multilayer circuit board of multi-row construction according to the ninth embodiment.

### DETAILED DESCRIPTION OF THE PREFERRED EMBODIMENTS

First Embodiment

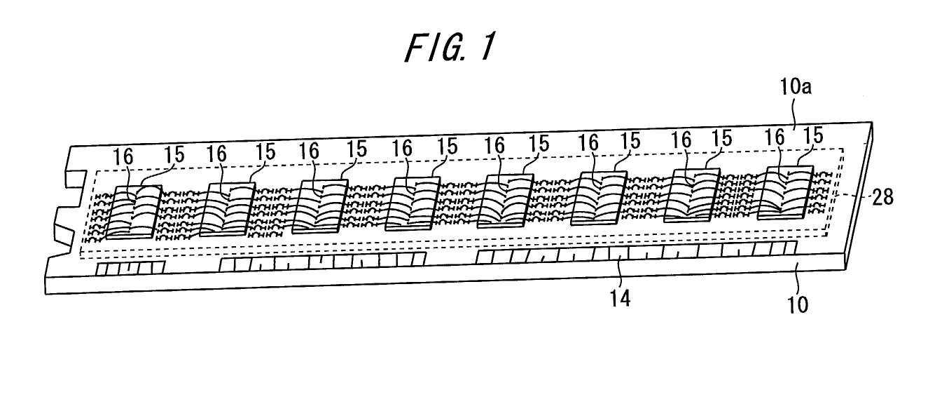

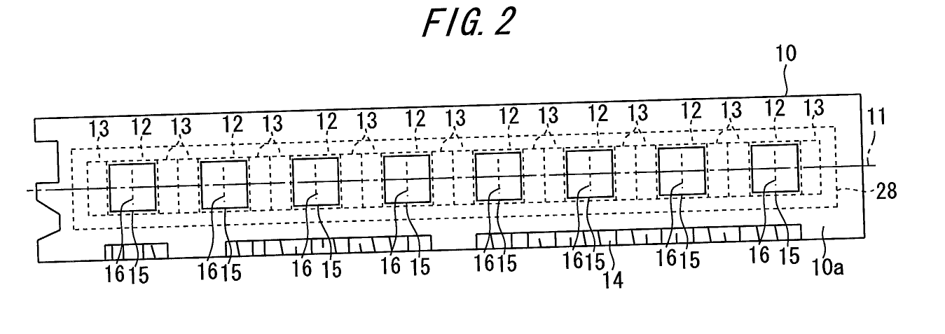

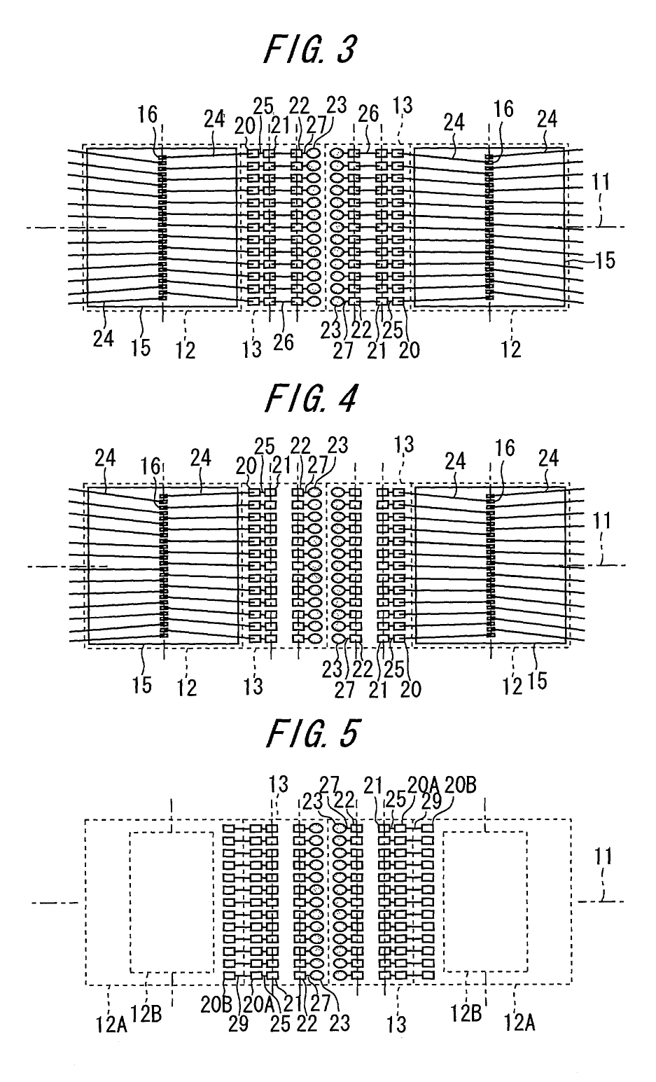

FIGS. 1 through 4 show a first embodiment of the present invention, and the first embodiment corresponds to a first example of a memory module according to the present invention. FIG. 1 is a perspective view of a memory module, showing the memory module while molding resin applied over the module is removed. FIG. 2 is a top view showing the layout of the upper surface of the memory module shown in FIG. 1. FIG. 3 is an enlarged top view showing a portion of the memory module shown in FIG. 2; more specifically, two adjacent chips and a wiring space provided therebetween. FIG. 4 is a top view showing the memory module shown in FIG. 3 before the chips are wire-bonded. Since FIG. 1 roughly shows wiring provided on the upper surface of the module, please refer to FIGS. 3 and 4 for accurate wiring.

The memory module according to the first embodiment illustrated in FIGS. 1 through 4 is formed through use of a multilayer circuit board 10. The multilayer circuit board 10 is formed by lamination of a plurality of circuit boards and has the geometry of an elongated rectangular. A circuit board 10a which is the top layer of the multilayer circuit board 10 has provided thereon a plurality of chip mount areas 12 along the center line 11 with reference to the longitudinal direction of the multilayer circuit board 10. Each chip mount area 12 is an area where a semiconductor memory chip is to be mounted. Since a rectangular memory chip is used herein, each chip mount area 12 is formed into a rectangular shape. The chip mount areas 12 are arranged in a row with wiring spaces 13 interposed therebetween. Edge terminals 14 are formed along one of the longitudinal edges of the circuit board 1a for enabling establishment of electrical connection between the multilayer circuit board 10 and another electric circuit or an electric device.

A rectangular semiconductor memory chip 15 is fixedly bonded to a corresponding chip mount area 12. The semiconductor memory chip 15 is a bare chip having a row of electrode pads 16 on the upper surface. A row of electrode pads 16 are formed along the longitudinal center line of the memory chip 15 so as to cross the center line 11 at right angles.

The wiring spaces 13 are provided adjacent to the corresponding chip mount are as 12. More specifically,the wiring spaces 13 is arranged both sides of the chip mount area 12 along the center line 11, then the wiring spaces 13 and the chip mount areas 12 are arranged in an alternating manner. As can be seen from the enlarged view shown in FIG. 3, bonding pads of bonding pad group 20, contact pads of contact pad group 21, jumper pads of jumper pad group 22, and through holes of through hole group 23 are arranged in each wiring space 13 in the form of rows that cross the center line 11 at right angles.

Bonding pads of the bonding pad group 20 are provided in a position closest to the chip mount area 12. Individual electrode pads of the electrode pad row 16 laid on each memory chip 15 are connected to respective bonding pads of the row of bonding pads 20 by way of bonding wires 24. In the present embodiment, individual electrode pads of the electrode pad row 16 are connected to the adjacent bonding pad group 20 provided on either side of the memory chip 15 such that one electrode pad is connected to a bonding pad group 20 on one side of the memory chip 15 and the next electrode pad along the longitudinal center line of the memory chip 15 is connected to another bonding pad group 20 on the other side of the memory chip 15.

Contact pads of the contact pad group 21 are identical in number to bonding pads of the bonding pad group 20. The contact pad group 21 is placed adjacent to the bonding pad group 20, and the contact pads are respectively connected to corresponding bonding pads by way of respective connection patterns 25. The jumper pad group 22 is arranged adjacent to the contact pad group 21, and jumper pads of the jumper pad group 22 are equal in number to contact pads of the contact pad group 21. Jumper pads of the jumper pad group 22 are respectively connected to corresponding contact pads of the contact pad group 21 by way of respective jumper wires 26.

A through hole group 23 is arranged adjacent to the jumper pad group 22. Through holes of the through hole group 23 are equal in number to the jumper pads of the jumper pad group 22. The through holes are respectively connected to corresponding jumper pads of the adjacent jumper pad group 22 by way of respective connection patterns 27. Individual through holes of the through hole group 23 are connected to another portion of the multilayer circuit board 10 by way of the top layer of the circuit board 10a and another layer of the same,as required. More specifically, some through holes are connected to another circuit element provided on another layer of the multilayer circuit board 10, and other through holes are connected to the edge terminal 14 (connection portion) of the circuit board 10a. Then the memory chip 15 is connected to another electric circuit or electric device by way of the edge terminal 14.

The first embodiment is effective for testing the electric properties of an individual semiconductor memory chip 15 during the course of manufacture. The memory chip 15 is tested while remaining in a state shown in FIG. 4. In the state shown in FIG. 4, jumper wires 26 are not yet provided. The row of electrode pads 16 provided on the memory chip 15 is connected to bonding pads of the bonding pad groups 20 by way of the bonding wires. Each bonding pads of the bonding pad group 20 are further connected to respective contact pads of contact pad group 21 by way of respective connection patterns 25. Since jumper wires 26 are not yet provided on the circuit board 10a, the contact pads 21 are not connected to the jumper pads 22 and subsequent circuits.

Testing of a semiconductor memory chip 15 is performed by means of loading data from unillustrated test equipment to some contact pads of the contact pad group 21 while the memory chip 15 is in a state shown in FIG. 4; reading output data from other contact pads of the contact pad group 21; and comparing the loaded data with the output data. If a match is found between the data sets, the memory chip 15 is determined to be non-defective. In contrast, if no match is found, the memory chip 15 is determined to be defective. The jumper pad group 22 is connected to another circuit element or another connection portion by way of the through hole group 23. Such connection acts as a load on the memory chip 15 and hinders efficient testing of the memory chip 15. However, in the state shown in FIG. 4, no such load is exerted on the memory chip 15, and hence efficient testing of a memory chip 15 is accomplished.

Molding resin 28 is indicated by broken lines in FIGS. 1 and 2, and the multilayer circuit board 10 is illustrated while the molding resin 28 is removed from the multilayer circuit board 10. If a test result shows that all the memory chips 15 are non-defective, contact pads of the contact pad groups 21 and jumper pads of the jumper pad groups 22 are respectively connected by means of the jumper wires 26. Subsequently, the multilayer circuit board 10 is sealed with the molding resin 28. The molding resin 28 hermetically encapsulates therein all the memory chips 15, the bonding pad groups 20, the contact pad groups 21, the jumper pad groups 22, the through hole groups 23, the bonding wires 24, the connection patterns 25, the jumper wires 26, and the connection patterns 27.

Second Embodiment

FIG. 5 shows a second embodiment of the present invention, and the second embodiment corresponds to a second example of the memory module according to the present invention. FIG. 5 shows two adjacent chip mount areas 12A and 12B provided on a multilayer circuit board and a wiring space 13 defined between the chip mount areas 12A and 12B while the memory chips 15 are not yet mounted on the multilayer circuit board. The bonding wires 24 and the jumper wires 26 are not yet formed.

In the present embodiment, two bonding pad groups 20A and 20B are provided side by side, and individual bonding pads of the bonding pad groups 20A and 20B are respectively connected together by way of connection patterns 29. The bonding pad group 20A is assigned to the first chip mount area 12A, and the bonding pad group 20B is assigned to the second chip mount area 12B. Thus, the memory module becomes compatible with memory chips of different sizes.

The chip mount areas 12A and 12B are of different sizes and are compatible with memory chips of different respective sizes. In a case where a larger memory chip is mounted in the chip mount area 12A, the bonding pad group 20B is hidden behind the memory chip. In such a case, the bonding pad group 20B is not used, and the bonding pad group 20A is used for establishing connection between the memory chip and the row of electrode pads 16.

In a case where a smaller memory chip is mounted in the chip mount area 12B, the row of electrode pads 16 are respectively connected to the bonding pads of the bonding pad group 20B by means of the bonding wires 24.

Third Embodiment

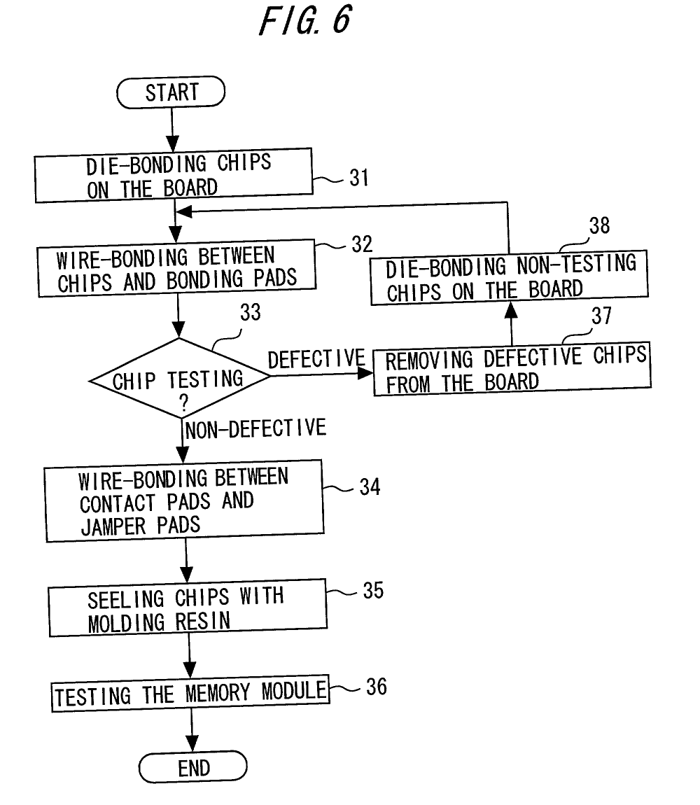

A third embodiment corresponds to a first example of method of manufacturing a memory module according to the present invention. The first example of the manufacturing method corresponds to the memory module shown in FIGS. 1 through 4. FIG. 6 is a flow chart showing the first example of the manufacturing method.

FIG. 6 includes eight steps from the beginning to the end of the manufacturing method. In Step 31, a plurality of memory chips 15 are die-bonded to the respective chip mount areas 12 on the multilayer circuit board 10. In step 32, the row of electrode pads 16 of respective memory chip 15 are wire-bonded to the bonding pad group 20. As mentioned previously, after wire-bonding of the electrode pads 16, the electric properties of the individual memory chip 15 are tested in step 33. If the test result shows that all the memory chips 15 are non-defective, in step 34 the contact pad group 21 is connected to the jumper pad group 22 by means of the jumper wires 26. In step 35, the memory chips 15 are sealed with the molding resin 28. The electric properties of the memory module are tested in step 36, wherewith manufacture of a memory module is completed.

If the test result obtained in step 33 shows that any of the memory chips 15 are defective, the defective chips are replaced with non-tested memory chips; for example, new memory chips. More specifically, in step 37 the defective memory chips are removed from the multilayer circuit board 10, and in step 38 non-tested memory chips 15 are mounted on the circuit board 10. Subsequently, the row of electrode pads 16 of each of the thus-newly-mounted memory chips 15 are respectively connected to the corresponding bonding pads of the bonding pad group 20 by means of bonding wires 24. In step 33 the electric properties of the memory chips 15 are tested, and processing pertaining to steps 37, 38, 32, and 33 is repeated until the memory chips 15 are determined to be non-defective.

According to the method of manufacturing a memory module according to the third embodiment, the memory chips 15 are tested before being sealed with the molding resin 28. Even if defective chips are found, the defective memory chips can be readily replaced with non-defective memory chips by means of removing the bonding wires 24, thus diminishing financial losses and consumption of effort. Since memory chips are tested on the multilayer circuit board 10 on which the memory chips are to be mounted, there can be eliminated inconvenience which would otherwise be caused by preparing a special test socket. Since memory chips are tested before bonding of the jumper wires 26, the memory chips can be effectively tested with smaller load.

Fourth Embodiment

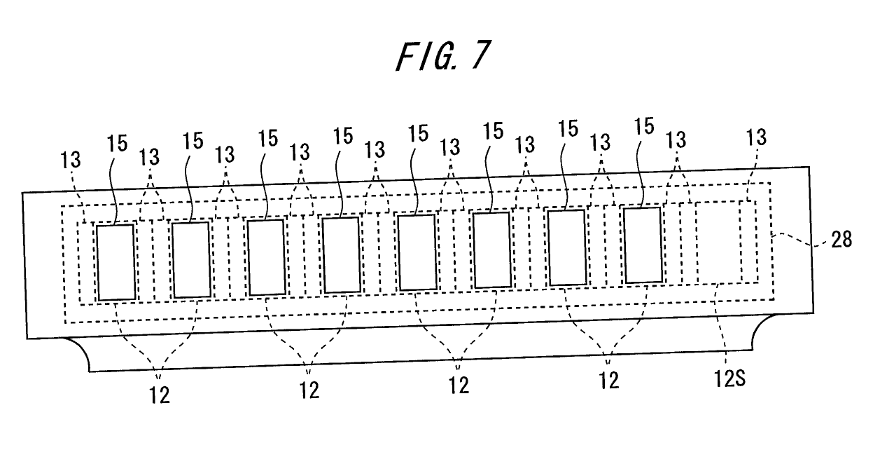

A fourth embodiment of the present invention corresponds to a third example of the memory module according to the present invention. FIG. 7 is a top view showing the fourth embodiment. In the present embodiment, a plurality of regular chip mount areas 12 are provided on the multilayer circuit board 10 together with a spare chip mount area 12S. The regular chip mount areas 12 are provided in the minimum number required f or constituting a memory module. In the example shown in FIG. 7, eight regular chip mount areas 12 are formed. A spare chip mount area 12S is additionally formed along with the eight regular chip mount areas 12. Although a plurality of spare chip mount areas 12S may be formed, only one spare chip mount area 12S is formed in the example shown in FIG. 7. As illustrated in FIG. 7, the wiring space 13 is provided on either side of each regular chip mount area 12, as in the case of the first embodiment. Similarly, the wiring space 13 is provided on either side of the spare chip mount area 12S. As in the case of the first embodiment, the bonding pad groups 20, the contact pad groups 21, the jumper pad groups 22, and the through hole groups 23 are formed, and the connection patterns 25 and 27 are also formed in the wiring space 13 in the same manner as that mentioned in connection with the first embodiment.

In a case where any of the semiconductor memory chips 15 mounted in the regular chip mount areas 12 is determined to be defective through an operation test, a new non-tested spare memory chip is mounted in the spare chip mount area 12S. If the spare memory chip is determined to be non-defective through a test, the contact pad group 21 assigned to the spare memory chip are connected to the corresponding jumper pad group 22 by means of the jumper wires 26, whereby the spare memory chip is used as a true memory chip. Although the memory chip 15 which has been determined to be defective still remains on the circuit board, the contact pad group 21 assigned to the defective memory chip 15 is not connected to the corresponding jumper pad group 11, and hence the defective memory chip 15 does not contribute to the operation of the memory module.

Fifth Embodiment

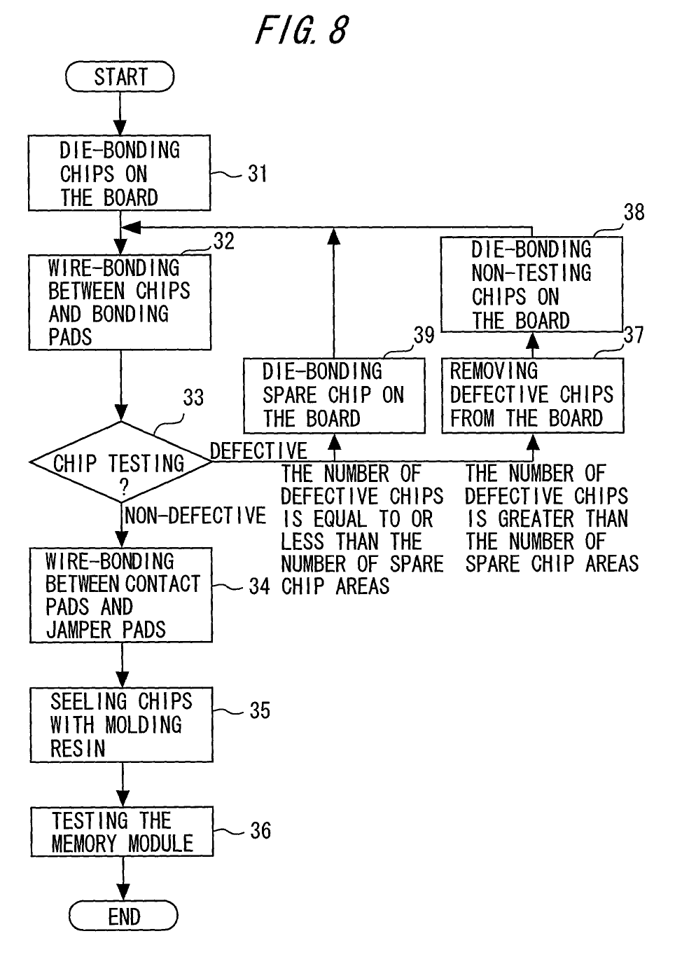

A fifth embodiment is a second example of the method of manufacturing a memory module according to the present invention. The method according to the fifth embodiment is similar to that described in connection with the fourth embodiment. FIG. 8 is a flowchart showing processing pertaining to the method.

According to the flowchart shown in FIG. 8, in a case where some memory chips 15 are determined to be defective in step 33 of the test, processing pertaining to step 37 and/or processing pertaining to step 39 (are) is performed. If the number of memory chips 15 which have been determined to be defective is equal to or less than the number of spare chip mount areas 12S, only processing pertaining to step 39 is performed. In this case, in step 39 a new untested memory chip 15 is mounted in the spare chip mount area 12S as a substitute for the memory chip 15 which has been determined to be defective. In step 32, the row of electrode pads 16 are respectively wire-bonded to the corresponding bonding pad group 20, and the memory chips 15 are again tested in step 33.

In a case where the number of memory chips 15 which have been determined to be defective is greater than the number of available spare chip mount areas 12S, only spare memory chips 15 equal in number to the spare mount areas 12S are mounted first, and in step 37 the remaining defective memory chips 15 are replaced with new memory chips.

If the memory chips 15 in number required for constituting a memory module are determined to be non-defective, the memory chips 15 are connected by means of jumper wires 26 in step 34. More specifically, contact pads of the contact pad groups 21 corresponding to the memory chips 15—which have been determined to be non-defective and include the memory chips 15 mounted in the spare chip mount areas 12S—are respectively connected to corresponding jumper pads of the jumper pad groups 22. The memory chips 15 which have been determined to be defective remain in their present forms. While the contact pad groups 21 corresponding to the defective memory chips 15 are not connected to corresponding jumper pad groups 22, all the memory chips 15 are encapsulated in molding resin 28. Therefore, the defective memory chips 15 will not contribute to the operation of the memory module.

Sixth Embodiment

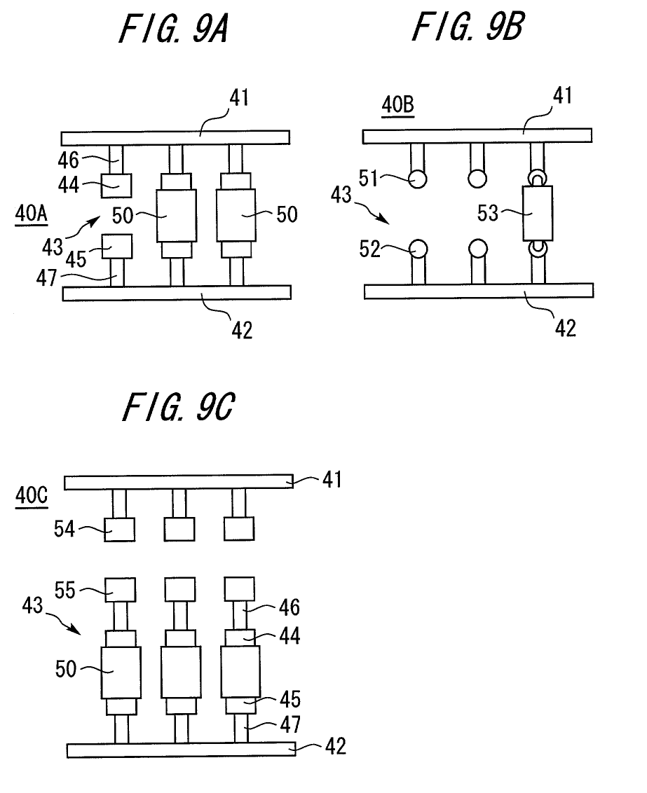

A sixth embodiment of the present invention is a fourth example of a memory module according to the present invention. The multilayer circuit board 10 used in the present embodiment is of the same construction as the memory modules described in the first, second, and fourth embodiments. The memory module according to the present embodiment further additionally includes any one of a circuit pattern 40A shown in FIG. 9A, a circuit pattern 40B shown in FIG. 9B, and a circuit pattern 40C shown in FIG. 9C. The circuit patterns 40A, 40B, and 40C can enable addition of a capacitor for reducing power noise. Circuit patterns are incorporated into the multilayer circuit board 10 so as to correspond to respective memory chips 15.

In the circuit pattern 40A shown in FIG. 9A, a plurality of capacitor addition circuits; for example, three capacitor addition circuits 43, are provided between a power line 41 connected to a power source and a reference voltage line 42 connected to a reference voltage such as a ground potential. In the example shown in FIG. 9A, the capacitor addition circuit 43 comprises a pair of capacitor connection pads 44 and 45. The power-side connection pad 44 is connected to the power line 41 by way of the connection pattern 46, and the reference-potential-side connection pad 45 is connected to the reference voltage line 42 by way of the connection pattern 47.

In a case where the memory chip 15 which has been determined to be defective and the cause is considered to be attributable to power noise, the circuit pattern 40A is used for additionally connecting a required number of power noise reduction capacitors 50 of chip type to the memory chip 15. The circuit pattern 40A is suitable for additional connection of the chip capacitor 50.

The circuit pattern 40B shown in FIG. 9B is a capacitor addition circuit utilizing a through hole. In this example, the respective capacitor addition circuit 43 has a pair consisting of through holes 51 and 52. The through hole 51 is connected to the power line 41, and the through hole 52 is connected to the reference voltage line 42. The circuit pattern 40B is used for additionally connecting a power noise reduction capacitor 53 having a pair of leads. A plurality of capacitors 53 are available, and a pair of leads of the capacitor 53 are inserted into and brazed to the corresponding through holes 51 and 52.

In the circuit pattern 40C shown in FIG. 9C, a pair consisting of capacitor jumper pads 54 and 55 is assigned to each power-side connection pad 44 of the circuit pattern 40A shown in FIG. 9A such that the jumper pads 54 and 55 are interposed between the power-side connection pad 44 and the power line 41. In the circuit pattern 40C, the chip capacitor 50 is provided between each set of paired pads 44 and 45. A required number of capacitors 50 are connected to the circuit by means of selectively establishing connection across a set of paired jumper pads 54 and 55.

Seventh Embodiment

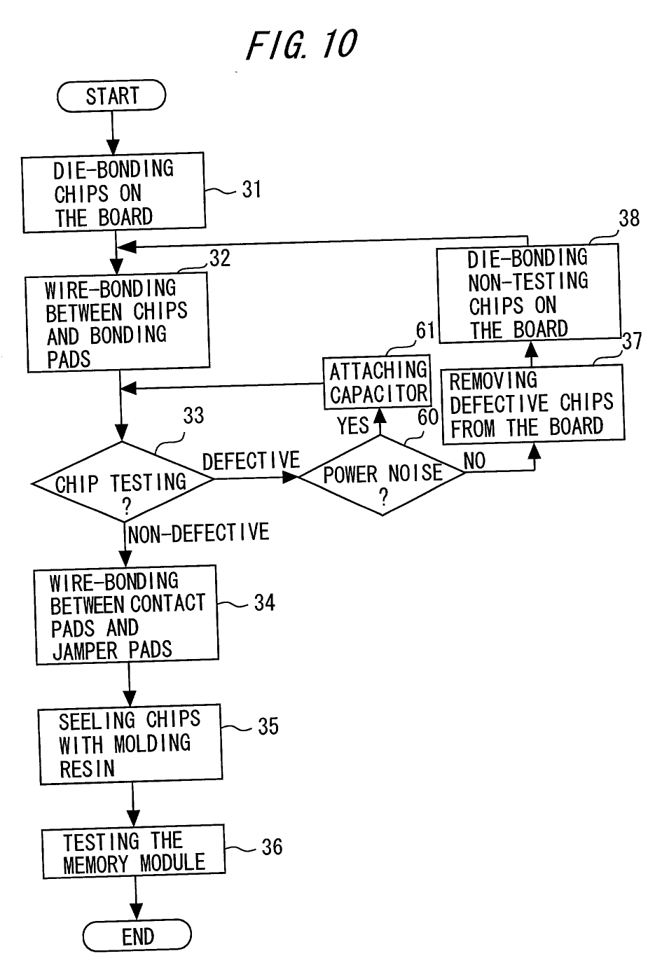

A seventh embodiment corresponds to a third example of the method of manufacturing a memory module according to the present invention and is similar to the sixth embodiment. FIG. 10 shows a flowchart of the manufacturing method. According to the manufacturing method, processing pertaining to step 60 subsequent to step 33 takes into consideration causes of fault of the defective memory chip 15, and a determination is made as to whether or not defects of the defective memory chip 15 are due to power noise. Specifically, the defective memory chip 15 is again tested through use of a smaller power voltage. If the memory chip 15 passes the test, defects of the memory chip 15 are considered to be attributable to power noise. In step 61, a power noise reduction capacitor is additionally attached to the memory chip 15. In step 33, the memory chip 15 is again tested. In step 61, where a power noise reduction capacitor is to be attached to a memory chip, there is used any one of the circuit patterns 40A shown in FIG. 9A, 40B shown in FIG. 9B, and 40C shown in FIG. 9C. If power noise has been determined not to be the cause of the memory chip failing the test, processing pertaining to step 32 is performed by way of steps 37 and 38. Subsequently, the memory chip is again tested in step 33.

According to the seventh embodiment, in a case where defects of the defective memory chip are attributable to power noise, a power noise reduction capacitor is additionally attached to the memory chip with relative ease and without involvement of replacement of a memory chip, thereby improving consumption of effort and costs to a much greater extent.

Eighth Embodiment

An eighth embodiment corresponds to a fourth example of the method of manufacturing a memory module according to the present invention. The manufacturing method according to the present embodiment employs a multilayer circuit board 100 having a multi-row construction. The multilayer circuit board 100 is constituted by means of integrated incorporation of a plurality of multilayer circuit boards 10. FIG. 11 shows an example of the multilayer circuit board 100. The multilayer circuit board 100 shown in FIG. 11 incorporates fourth multilayer circuit board units 10. The multilayer circuit board unit 10 has the same construction as the multilayer circuit board 10 shown in FIGS. 1 through 4. As a matter of course, the memory module is not yet encapsulated with the molding resin 28, and memory chips are not yet connected by the jumper wires 26.

Manufacture of a memory module through use of the multilayer circuit board 100 of multi-row construction can improve efficiency of manufacturing operation as compared with a case where a memory module is assembled from independent multilayer circuit boards 10. In the case of a memory module comprising the multilayer circuit board 100 of multi-row construction, all the multilayer circuit board units 10 can share a set of bonding pad groups 20, a set of contact pad groups 21, a set of jumper pad groups 22, a set of through-hole groups 23, and connection patterns 25 and 27. All the multilayer circuit board units 10 are commonly subjected to all the steps shown in FIGS. 6, 8, and 10, with the exception of the module test in step 36. After the multilayer circuit board 100 has been encapsulated with molding resin 28, the multilayer circuit board units 10 are separated into pieces. Subsequently, the individual circuit board units 10 are subjected to the module test in step 36.

Ninth Embodiment

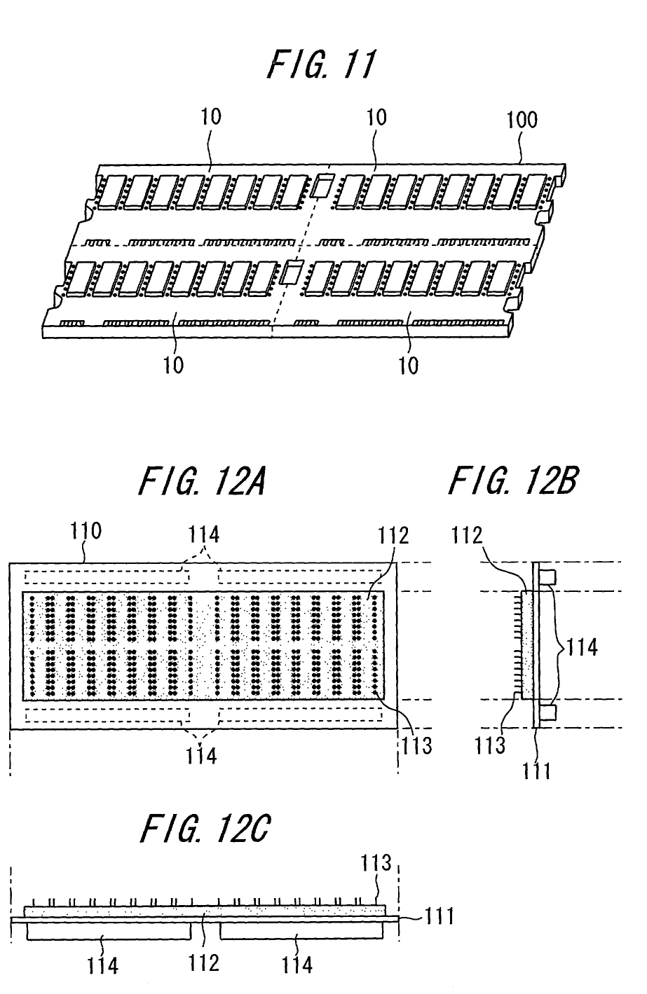

A ninth embodiment corresponds to a first example of a test connector for use with the memory module according to the present invention. A test connector 110 is shown in FIGS. 12A to 12C. FIG. 12A is a top view of the test connector 110; FIG. 12B is a right-side elevation view of the same; and FIG. 12C is a side view of the same. The test connector 110 shown in FIGS. 12A to 12C is used with the multilayer circuit board 100 of multi-row construction according to the eighth embodiment shown in FIG. 11.

The test connector 110 is formed by means of bonding a POGO-pin block 112 made of plastic-based resin to a connector multilayer wiring board 111. A plurality of POGO pins 113 are arranged on the POGO-pin block 112 and are assigned to all the contact pad groups 21 provided on the respective multilayer circuit board units 10. The POGO pins 113 are equal in number to all the connector pads and are arranged so as to correspond to the respective connector pads. Four plug-in connectors 114 are provided on the lower surface of the connector multilayer wiring board 111 and are allocated to the respective multilayer circuit board units 10. The plug-in connector 114 has connector pins to be connected to all the POGO pins 113 assigned to the respective pads of all the contact pad groups 21 provided on respective multilayer circuit board units 10.

There is prepared, as a standard test connector, a test connector 110 having POGO pins 113 which are greater in number than POGO pins to be actually used. It is also possible that at the time of actual use of a test connector 110 unnecessary POGO pins 113 are removed so as to match the construction of a memory module.

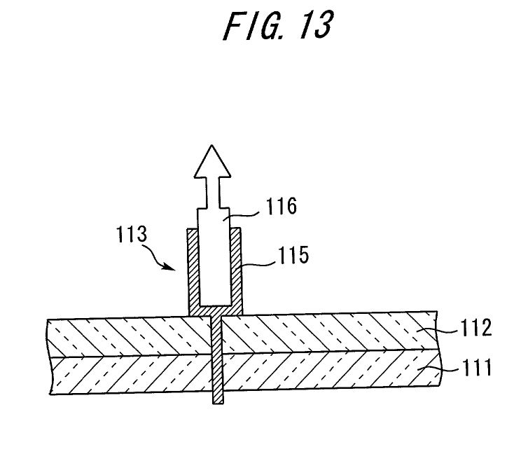

FIG. 13 shows the construction of a single POGO pin 113. The POGO pin 113 is constituted from a contact needle 116 resiliently supported within a POGO pin socket 115. The POGO pin socket 115 is connected to a corresponding connector 114 after having penetrated through the block 112 and the multilayer wiring board 111.

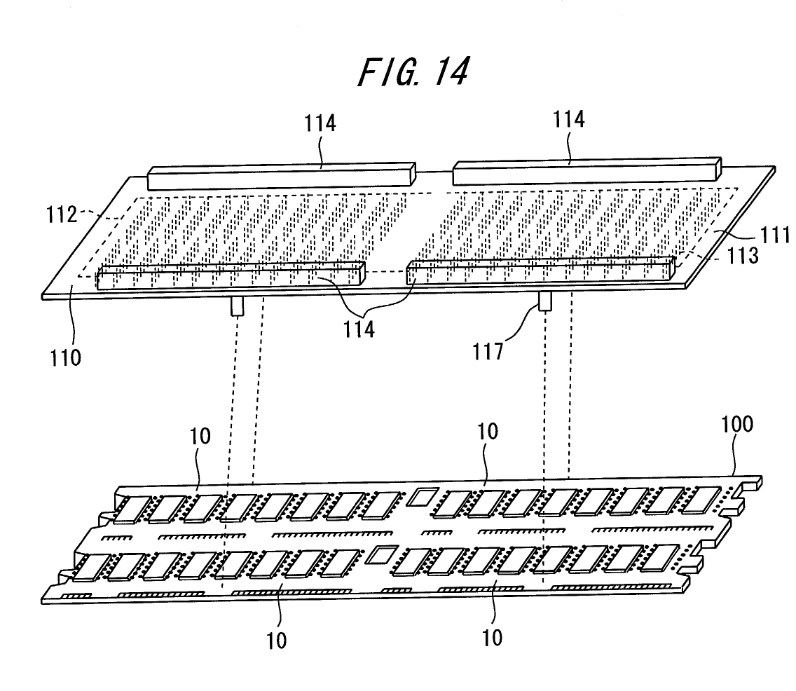

FIG. 14 shows a test connector 110 and a multilayer circuit board 100 of multi-row construction. In the test connector 110, a plurality of POGO pins 113 are provided in a multi-row pattern so as to oppose the upper surface of the multilayer circuit board 100; that is, the surface on which the contact pad groups 21 are provided. While being positioned by positioning pins 117 provided on the test connector 110, the test connector 110 is brought into contact with the multilayer circuit board 10 arranged in a multi-row pattern. In this state, all the POGO pins 113 are brought into electrical contact with all the contact pads of the contact pad groups 21, and memory chips are tested in step 33. As mentioned previously, a test is conducted while the row of electrode pads 16 provided on the respective memory chip 15 are bonded to the bonding pad groups 20 by means of bonding wires 24 and while the bonding pads are not yet connected by the jumper wires 26. The plug-in connectors 114 are connected to an unillustrated test device or test circuit.

Thus, the test connector 110 having a plurality of POGO pins 113 assigned to all contact pads of the contact pad groups 21 of at least one circuit board unit 10 facilitates testing of memory chips of a memory module and shortens test time.

As mentioned above, a memory module according to the present invention has a set of contact pad groups connected to respective memory chips and a set of jumper pad groups connected to other connection portions or circuit elements of a multilayer circuit board. The memory chips can be tested by means of utilization of the group of contact pads before the memory module is encapsulated with molding resin. As compared with a case where memory chips are tested after having been encapsulated with resin, the present invention can reduce the efforts and costs required for replacing defective memory chips with new, non-defective memory chips. Since memory chips can be tested while mounted on a multilayer circuit board on which the chips are to be mounted, use of special test sockets is obviated.

Further, a memory module according to the present invention is arranged so that memory chips of different sizes can be mounted in chip mount areas. Therefore, the memory module is compatible with memory chips of different sizes and yields the same advantage as that mentioned previously.

A memory module according to the present invention is provided with additional spare chip mount areas in conjunction with the minimum number of chip mount areas. Spare memory chips can be mounted in spare chip mount areas as substitutes for defective memory chips. Therefore, replacement of defective memory chips can be performed in a simpler manner.

So long as the memory module according to the present invention is provided with circuit patterns for use in connecting power noise reduction capacitors to memory chips, memory chips which have been determined to be defective for reasons of power noise can be recovered to a non-defective state by means of taking simple measures.

Under a method of manufacturing a memory module according to the present invention, memory chips are tested before being encapsulated with molding resin, by means of utilization of a group of contact pads. As compared with a memory module which is subjected to a chip test after having been encapsulated with resin, a memory module according to the present invention can reduce efforts and costs required for replacing defective memory chips with non-defective memory chips. Further, memory chips can be tested while mounted on a multilayer circuit board on which the memory chips are to be mounted, and hence use of a special test socket is obviated. Further, memory chips are tested while separated from a module circuit including a set of jumper pad groups, and hence memory chips can be tested efficiently and accurately.

Under the method of manufacturing a memory module according to the present invention, processing pertaining to some steps of the processes for manufacturing a plurality of memory modules can be performed commonly, thereby reducing manufacturing costs further.

The method of manufacturing a memory module according to the present invention employs a multilayer circuit board having spare chip mount areas in addition to the minimum required chip mount areas. As a result, spare memory chips can be mounted in the spare chip mount areas as substitutes for memory chips which have failed the test. Thus, memory chips which have failed the test can be readily replaced with non-defective memory chips. Therefore, replacement of defective memory chips can be performed in a simpler manner.

The method of manufacturing a memory module according to the present invention employs a multilayer circuit board having circuit patterns which enable connection of power noise reduction capacitors. Therefore, memory chips which have been determined to be defective for reasons of power noise can be readily recovered to a non-defective state by means of taking simple measures.

A test connector for use with a memory module according to the present invention is provided with a group of POGO pins which are brought into contact with all contact pads of all contact pad groups. Hence, testing of memory chips can be implemented in a shorter period of time.

The entire disclosure of a Japanese Patent Application No. 2000-259661, filed on Aug. 29, 2000 including specification, claims, drawings and summary, on which the Convention priority of the present application is based, are incorporated herein by reference in its entirety.

1. A memory module comprising:
a multilayer circuit board having a plurality of chip mount areas on which a plurality of semiconductor memory chips are to be mounted;
a plurality of bonding pad groups which are formed on said multilayer circuit board so as to correspond to the respective chip mount areas and are respectively connected to electrode pads of the corresponding semiconductor memory chips;
a plurality of contact pad groups which are formed on said multilayer circuit board so as to correspond to the respective bonding pad groups and are respectively connected to corresponding bonding pad groups;
a plurality of jumper pad groups which are formed on said multilayer circuit board so as to correspond to the respective contact pad groups and are respectively connected to other connective portions or other circuit elements provided on said multilayer circuit board;
a plurality of jumper wires for interconnecting the jumper pad groups and corresponding contact pad groups respectively; and
molding resin for encapsulating said memory chips, said bonding pad groups, said contact pad groups, said jumper pad groups, and said jumper wires.

2. The memory module according to claim 1, wherein the respective chip mount area is formed so as to enable mounting of either a first semiconductor memory chip or a second semiconductor memory chip, which differ in size from each other, and said bonding pad group has both a first bonding pad group assigned to said first memory chip and a second bonding pad group assigned to said second memory chip.

3. The memory module according to claim 1, wherein said multilayer circuit board has at least one spare chip mount area to be used for mounting a spare semiconductor memory chip, in addition to a plurality of chip mount areas on which a minimum required number of semiconductor memory chips are to be mounted.

4. The memory module according to claim 1, wherein said multilayer circuit board has a circuit pattern for enabling connection of a plurality of power noise reduction capacitors between a power line and a ground line.

5. A method of manufacturing a memory module, comprising:
a preparation step for preparing a multilayer circuit board having
a plurality of chip mount areas for use in mounting a plurality of semiconductor memory chips,
a plurality of bonding pad groups assigned to the respective chip mount areas,
a plurality of contact pad groups respectively connected to the corresponding bonding pad groups, and
a plurality of jumper pad groups which are respectively arranged so as to correspond to the respective contact pad groups and are respectively connected to other circuit portions or circuit elements;
a first connection step for mounting semiconductor memory chips in the respective chip mount areas after the preparation step and connecting electrode pads of the respective semiconductor memory chips to the respective bonding pad groups assigned to the respective chip mount area;
a test step for testing the respective semiconductor memory chips by way of the respective contact pad groups after said first connection step, taking measures against the semiconductor memory chips which are determined to have failed the test, and testing said semiconductor memory chips again until said semiconductor memory chips are determined to have passed the test;
a second connection step for connecting the respective contact pad groups to corresponding jumper pad groups after said test step; and
a molding step for encapsulating, with molding resin, said semiconductor memory chips, said bonding pad groups, said contact pad groups, and said jumper pad groups after said second connection step.

6. The method of manufacturing a memory module according to claim 5, wherein said multilayer circuit board prepared in said preparation step has a multi-row construction; said multilayer circuit board of multi-row construction includes a plurality of circuit board units; and each of said circuit board units comprises said plurality of chip mount areas, said plurality of bonding pad groups assigned to the respective chip mount areas, said plurality of contact pad groups corresponding to the bonding pad groups; and said plurality of jumper pad groups corresponding to the respective contact pad groups.

7. The method of manufacturing a memory module according to claim 5, wherein said semiconductor memory chips which have been determined to be defective in said test step are replaced with other semiconductor memory chips.

8. The method of manufacturing a memory module according to claim 5, wherein said multilayer circuit board prepared in said preparation step includes a spare chip mount area for use in mounting a spare semiconductor memory chip, in addition to a plurality of chip mount areas for use in mounting a minimum required number of semiconductor memory chips; said spare semiconductor memory chip is mounted in said spare chip mount area if one of said semiconductor memory chips is determined to be defective in said test step; and electrode pads of said spare semiconductor memory chip are connected to corresponding bonding pad group, wherewith said spare semiconductor memory chip is tested.

9. The method of manufacturing a memory module according to claim 5, wherein said multilayer circuit board prepared in said preparation step has a circuit pattern for enabling connection of a plurality of power noise reduction capacitors between a power line and a ground line; and in a case where defects of semiconductor memory chips which have been determined to be defective by said test are considered to be attributable to power noise, required power noise reduction capacitors are connected to the semiconductor memory chips by use of said circuit pattern, and then said semiconductor memory chips are tested again.

10. A test connector for use in testing semiconductor memory chips in combination with a multilayer circuit board, the circuit board including a plurality of chip mount areas in which a plurality of semiconductor memory chips are to be mounted, a plurality of bonding pad groups assigned to the respective chip mount areas and respectively connected to electrode pads of the corresponding semiconductor memory chip, a plurality of contact pad groups respectively connected to the corresponding bonding pad groups, and a plurality of jumper pad groups which are arranged so as to correspond to the respective contact pad groups and are respectively connected to other circuit pads or circuit elements, comprising:
a plurality of POGO pin groups provided on said circuit board so as to correspond to the respective contact pad groups; and
a plurality of connector terminals provided on said circuit board and connected to the respective POGO pin groups.
